(19) United States
(12) Patent Application Publication
(10) Pub. No.: US 2006/0258135 A1
(43) Pub. Date: Nov. 16, 2006

(54) Semiconductor integrated circuit

(75) Inventors: Yasuyo Sogawa, Kadoma-shi (JP); Kazuhiko Nishikawa, Ibaraki-shi (JP); Masanori Hirofuji, Ibaraki-shi (JP)

Correspondence Address: STEPTOE & JOHNSON LLP, 1330 CONNECTICUT AVE., NW, WASHINGTON, DC, 20036, US

(73) Assignee: Matsushita Electtric Industrial Co., Ltd., Kadoma-shi (JP)

(21) Appl. No.: 10/565,006

(22) PCT Filed: Aug. 31, 2004
(86) PCT No.: PCT/JP04/12904

§ 371 Date: Jan. 18, 2006

(30) Foreign Application Priority Data
Sep. 22, 2003 (JP) 2003-330344

(51) Int. Cl. H01L 21/44; H01L 23/48

(52) U.S. Cl. 438/612; 257/737

(57) ABSTRACT

Each of plural semiconductor integrated circuits existing on a semiconductor wafer is provided with a function circuit (3), plural pads (4), and wirings (8) which are electrically connected to the pads (4) and contact bumps of a probe card (7), wherein at least two wirings (8a) and (8b) simultaneously contact one bump (6) in an area other than a bump area, without being in touch with each other, whereby wafer level burn-in is executed. Thereby, even when the chip area is reduced, wafer level burn-in can be carried out.

### TECHNICAL FIELD

The present invention relates to a semiconductor integrated circuit such as a LSI, and more particularly, to wafer level burn-in for the semiconductor integrated circuit.

### BACKGROUND ART

A plurality of semiconductor integrated circuits such as LSIs fabricated on a semiconductor wafer are subjected to an acceleration test (burn-in) for detecting initial failures before shipping. In this burn-in, an aging test is carried out at a high temperature (about 120˜150° C.) for a few hours.

Currently, a method of performing burn-in simultaneously on plural semiconductor integrated circuits in a wafer (wafer level burn-in) is proposed (e.g., Japanese Published Patent Application No. 2001-93947). When wafer level burn-in becomes practicable, burn-in can be carried out before packaging, whereby a reduction in cost for burn-in, such as a reduction in the number of failures to be packaged, can be expected.

Hereinafter, conventional wafer level burn-in will be described with reference to FIGS. 1 to 3. As shown in FIG. 1, plural semiconductor integrated circuits 2 such as LSIs are provided on a semiconductor wafer 1. As shown in FIG. 2, in each semiconductor integrated circuit 2, plural pads 4 are disposed on the periphery of a function circuit 3. When performing wafer level burn-in, it is necessary to apply a current to the plural pads 4. Therefore, bump contact areas 5 are provided on the respective pads 4, and plural bumps 6 provided on a probe card 7 are brought into contact with the bump contact areas 5 as shown in FIG. 3, to apply a current to the pads 4. Thereby, the semiconductor integrated circuits 2 in the wafer can be subjected to burn-in.

As described above, when performing wafer level burn-in to the conventional semiconductor integrated circuits, it is necessary to bring the bumps of the probe card into contact with the plural pads on the plural semiconductor integrated circuits disposed on the semiconductor wafer. As for the bumps of the probe card to be used for wafer level burn-in, there is a restriction that a predetermined interval between bumps must be secured. If the predetermined interval is not secured, no bumps can be fabricated. As a result, wafer level burn-in cannot be accurately performed. Therefore, when the number of semiconductor integrated circuits per wafer is increased with a reduction in the chip area of each semiconductor integrated circuit, the number of bumps per semiconductor integrated circuit chip must be decreased. Therefore, when the chip area of each semiconductor integrated circuit is reduced, it becomes impossible to fix all of the pads of the semiconductor integrated circuits on the semiconductor wafer by the bumps. As a result, wafer level burn-in cannot be carried out.

Accordingly, the present invention has for its object to provide a semiconductor integrated circuit on which wafer level burn-in can be carried out even when the chip area thereof is reduced.

### DISCLOSURE OF THE INVENTION

In order to solve the above-mentioned problems, a semiconductor integrated circuit according to claim 1 of the present invention includes pads, and wirings which are electrically connected to the pads, wherein said wirings are connected to bumps of a probe card, in an area other than an area where the pads are disposed. Therefore, when executing wafer level burn-in, the chip area of each semiconductor integrated circuit can be reduced without being influenced by the area where the pads are disposed, thereby reducing the cost for chip fabrication.

Further, according to claim 2 of the present invention, in the semiconductor integrated circuit defined in claim 1, at least two of the wirings contact one of the bumps. Therefore, even when the chip area of each semiconductor integrated circuit is reduced, wafer level burn-in can be carried out for all semiconductor integrated circuits on a semiconductor wafer.

Further, according to claim 3 of the present invention, in the semiconductor integrated circuit defined in claim 2, each of the wirings has at least one bent portion or angular portion. Therefore, the area of an electrode part that is a region where the bump of the probe card contacts the wirings can be secured more widely, thereby improving the contactability.

Further, according to claim 4 of the present invention, in the semiconductor integrated circuit defined in claim 2, the wirings have separable portions. Therefore, the operation quality of the semiconductor integrated circuit can be secured by only cutting the separable portion after wafer level burn-in. For example, interference of noise that is caused by short-circuiting of the wirings can be avoided.

### BRIEF DESCRIPTION OF THE DRAWINGS

FIG. 1 is a plan view of a semiconductor wafer.

FIG. 2 is a schematic diagram of a conventional semiconductor integrated circuit.

FIG. 3 is a diagram illustrating the states of a semiconductor wafer and a probe card during waver level burn-in.

FIG. 4 is a schematic diagram of a semiconductor integrated circuit according to a first embodiment.

FIG. 5 is a schematic diagram of a semiconductor integrated circuit according to a second embodiment.

FIG. 6 is an enlarged view of an electrode part 9 which is an area where wirings 8 contact a bump 6, in the semiconductor integrated circuit according to the second embodiment.

FIG. 7 is a diagram illustrating examples of shapes of the wirings 8.

FIG. 8 is an enlarged view of an electrode part 9 which is an area where wirings 8 contact a bump 6, in a semiconductor integrated circuit according to a third embodiment.

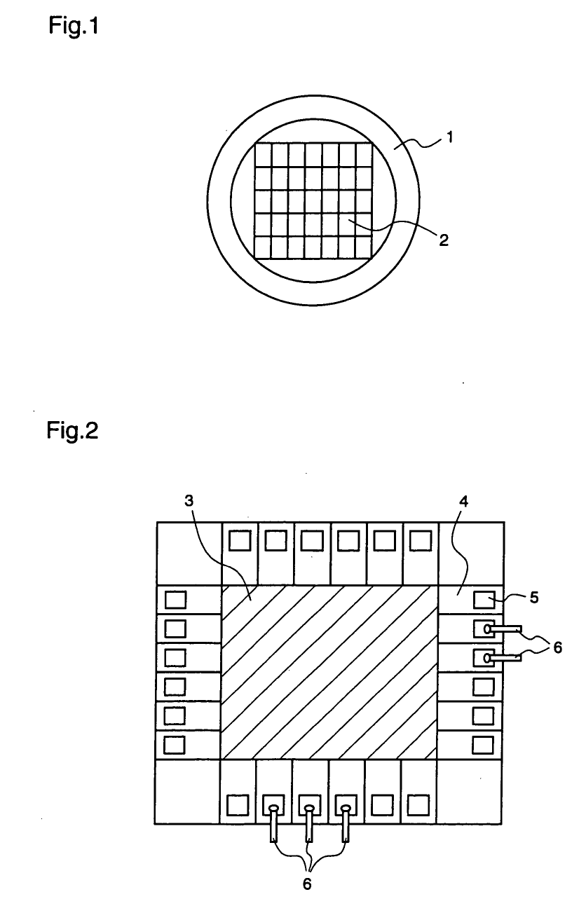

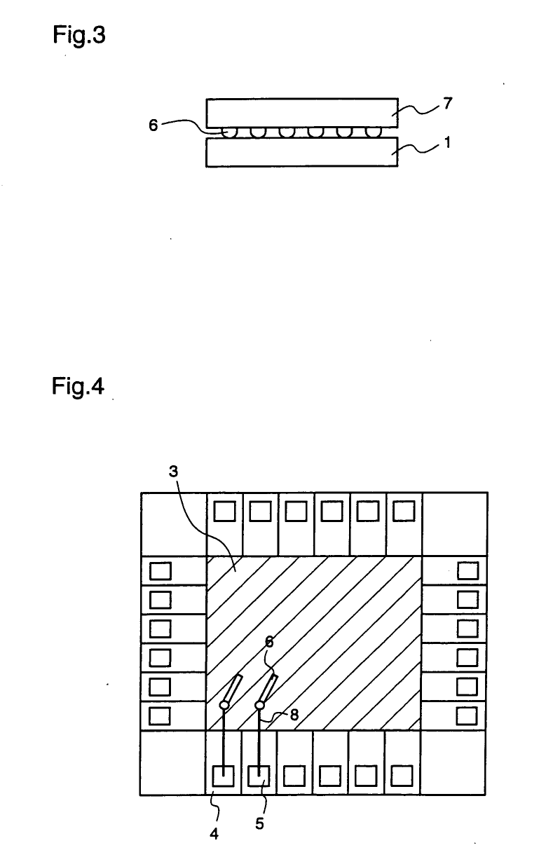

### BEST MODE TO EXECUTE THE INVENTION

### Embodiment 1

A semiconductor integrated circuit according to a first embodiment of the present invention will be described with reference to FIG. 4. FIG. 4 is a schematic diagram of the semiconductor integrated circuit according to the first embodiment. A plurality of semiconductor integrated circuits shown in FIG. 4 exist on a semiconductor wafer. The same constituents as those of the semiconductor integrated circuit shown in FIG. 2 are given the same reference numerals.

The semiconductor integrated circuit according to the first embodiment is characterized by that an electrode part is provided in an area other than the pad area. To be specific, as shown in FIG. 4, there is provided a wiring 8 which is electrically connected to an area on the pad 4, which area is a bump contact area in the conventional semiconductor integrated circuit. When executing wafer level burn-in, this wiring 8 contacts the bump 6 of the probe card 7, and the contact area serves as an electrode part. That is, in the semiconductor integrated circuit according to the first embodiment, when executing wafer level burn-in, the bump 6 contacts not the pad 4 but the wiring 8 placed in an area other than the pad area. While in the semiconductor integrated circuit shown in FIG. 4 the electrode part is provided in the area where the wiring 8 contacts the bump 6, i.e., the empty area in the function circuit 3, this electrode part may be provided in any area other than the pad area.

The above-mentioned semiconductor integrated circuit according to the first embodiment provides the following effects. In the conventional semiconductor integrated circuit wherein the bump contacts the pad during wafer level burn-in, the chip area depends on the area where the pad is disposed. This is because there is a restriction that a predetermined interval should be secured between adjacent bumps in the probe card and the pads must be disposed in accordance with the bump interval. Especially the chip area of the semiconductor integrated circuit in which the pads are disposed on the periphery of the function circuit as shown in FIG. 2 is greatly influenced by the pad area as compared with the function circuit area. Therefore, there are cases where, in the conventional semiconductor integrated circuit, the chip are cannot be reduced when executing wafer level burn-in. Accordingly, the semiconductor integrated circuit of the first embodiment is provided with the wiring 8 that is electrically connected to the pad 4, and the wiring 8 contacts the bump 6 of the probe card 7 in an area other than the area where the pad 4 is disposed. Thereby, even when executing wafer level burn-in, the chip area of the semiconductor integrated circuit can be reduced without being influenced by the area where the pad is disposed.

### Embodiment 2

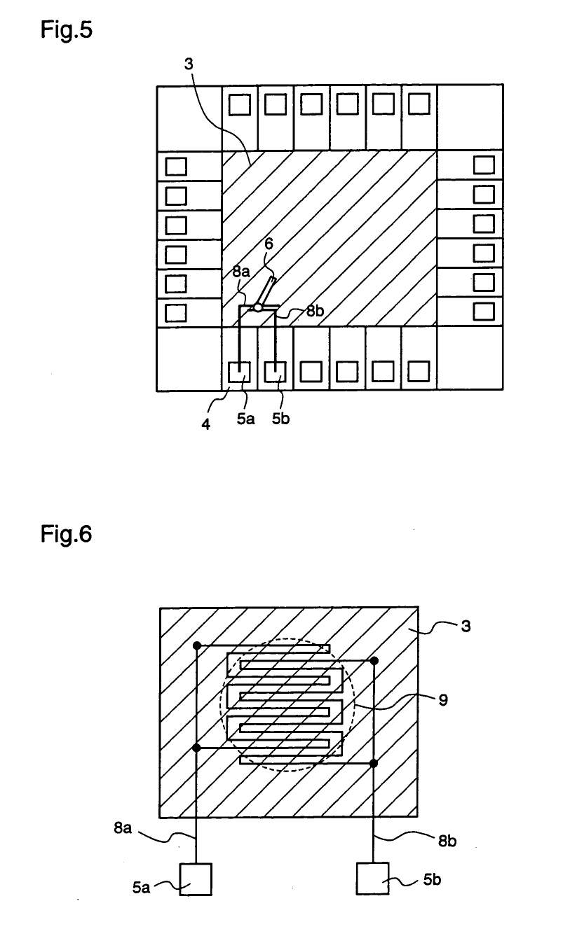

A semiconductor integrated circuit according to a second embodiment will be described with reference to FIGS. 5 to 7.

FIG. 5 is a schematic diagram illustrating the semiconductor integrated circuit according to the second embodiment. As shown in FIG. 5, the semiconductor integrated circuit of the second embodiment is constituted such that at least two wirings 8 simultaneously contact one bump 6. Hereinafter, a description will be given of the case where two wirings (wirings 8a and 8b) contact one bump 6.

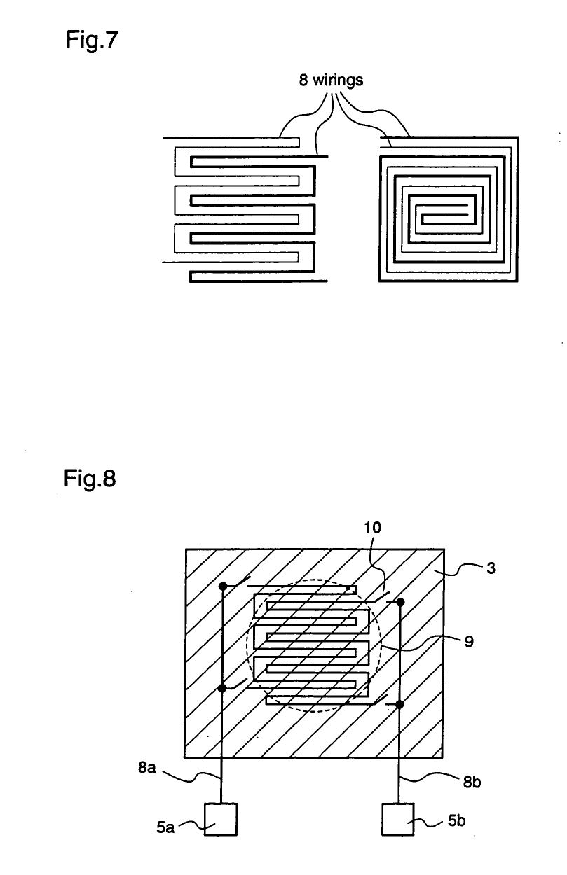

FIG. 6 is an enlarged view of an electrode part 9 that is an area where the wirings 8a and 8b contact the bump 6. As shown in FIG. 6, the wirings 8a and 8b are disposed so as not to contact each other but to contact the bump 6 simultaneously. The wirings 8a and 8b may have any shape such as a linear shape, a curved shape, or a dot shape. Preferably, each wiring should have at least one bent portion or angular portion so as to increase the area that contacts the bump 6. For example, a vent shape, and a comb-like shape and a whorl-like shape as shown in FIGS. 6 and 7 are preferable. Thereby, the area of the electrode part 9 that is a contact area of the wirings 8 with the bump 6 of the probe card 7 can be secured broadly, thereby to improve contactability.

As described above, the semiconductor integrated circuit according to the second embodiment is provided with the wirings 8 which are electrically connected to the pads 4, and at least two wirings 8 and one bump 6 contact each other in an area other than the bump area. Thereby, wafer level burn-in can be carried out with less number of bumps. As a result, it is possible to perform wave level burn-in for all the semiconductor integrated circuits on the semiconductor wafer even when the chip areas of the respective semiconductor integrated circuits are reduced.

While in this second embodiment the example where two wirings contact one bump has been described, the present invention is not restricted thereto. The number of wirings contacting one bump may be more than two.

### Embodiment 3

A semiconductor integrated circuit according to a third embodiment will be described with reference to FIG. 8.

FIG. 8 is an enlarged view of an electrode part of the semiconductor integrated circuit according to the third embodiment. As shown in FIG. 8, the semiconductor integrated circuit according to the third embodiment has a construction in which at least two wirings 8a and 8b and one bump 6 contact simultaneously. Further, the two wirings 8a and 8b include separable portions 10. In the semiconductor integrated circuit according to the third embodiment, the separable portions 10 of the wirings 8a and 8b are cut after wafer level burn-in, considering that a voltage difference might occur between the wirings 8a and 8b during actual operation after wafer level burn-in.

For example, the separable portion 10 may be a fuse or a switching element. A fuse is an element that is able to perform only one switching from ON to OFF, as disclosed in Japanese Published Patent Application NO. 52-67741. However, even when an area existing as an element cannot be clearly distinguished from other elements and wirings, if switching is possible in that area, it is considered that a fuse is connected to that area. Further, the separable portion 10 is not restricted to a fuse capable of onetime switching operation, and it may be a switching element capable of multiple times of switching.

As described above, in the semiconductor integrated circuit according to the third embodiment, the wirings 8 which are electrically connected to the pad 4 are provided, and the separable portions 10 are provided in the wirings 8. Therefore, the operation quality of the semiconductor integrated circuit can be secured during actual operation by only cutting the separable portions 10 after wafer level burn-in. For example, interference of noise that is caused by short-circuiting of the wirings can be avoided.

While in this third embodiment the example where two wirings contact one bump has been described, the present invention is not restricted thereto, and the number of wirings contacting one bump may be more than two.

### APPLICABILITY IN INDUSTRY

The present invention is useful as a semiconductor integrated circuit executing burn-in in wafer level.

1. A semiconductor integrated circuit including:
pads, and
wirings which are electrically connected to the pads,
wherein said wirings are connected to bumps of a probe card, in an area other than an area where the pads are disposed.

2. A semiconductor integrated circuit as defined in claim 1 wherein
at least two of said wirings contact one of said bumps without being in touch with each other.

3. A semiconductor integrated circuit as defined in claim 2 wherein
each of said wirings has at least one bent portion or angular portion.

4. A semiconductor integrated circuit as defined in claim 2 wherein
said wirings have separable portions.
